(19) United States
(12) Patent Application Publication
(10) Pub. No.: US 2009/0079447 A1
(43) Pub. Date: Mar. 26, 2009

(54) TESTING SYSTEM FOR A RADIO FREQUENCY MODULE

(75) Inventors: CHUNG-ER HUANG, TAIPEI (TW); SHENG-WEN CHEN, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: AZUREWAVE TECHNOLOGIES, INC., TAIPEI (TW)

(21) Appl. No.: 11/858,401

(22) Filed: Sep. 20, 2007

(51) Int. Cl. G01R 31/28

(52) U.S. Cl. 324/750

(57) ABSTRACT

A testing system for a RF module includes a metal casing formed a testing space therein, a RF testing socket disposed inside the testing module, and a pressing manipulator penetrating through the metal casing. A shielding material layer is disposed on the internal surface of the metal casing so that the RF signal is isolated inside the metal casing. An end of the pressing manipulator extends into the testing space. The pressing manipulator is controlled automatically and provides for a pressure on a RF module disposed on the testing module so as to execute a testing process. As mentioned above, the testing set for a RF module can prevent from RF testing interference and the testing manufacture efficiency is improved.

### BACKGROUND OF THE INVENTION

1. Field of the Invention

The present inventions relates to a testing system for a radio frequency module and in particular to a full automation RF testing system with anti-interference and high manufacture testing efficiency.

2. Description of Prior Art

Depending on the development of the communication technology, the wireless communication is extremely common for data transition or mobile service. For example, mobile phones, person digital assistant (PDA), and GPS are applied for many applications for modern life. The RFIC is an essential component for high frequency of the wireless communication products. However, the testing technique challenge of the RFIC is higher than that of the logic integrated circuit or memory IC.

On the other hand, because the applications of the RFIC are more and more extended, the integrality on single chip is more complicated. For instance, more functions such as Wireless LAN (WLAN), Bluetooth or GPS are combined on one single chip so that it is necessary to develop the solution for testing the multi-function module. In other words, the testing system has to meet the requirement of reliability so as to modify the repeatability and reproducibility of the testing results.

A shielding box is provided for a RF testing system in the related art and the operation of the shielding box is controlled manually. Accordingly, the shortcut of the testing process is the non-efficiency. Furthermore, the low precise testing is caused by the manual operation. Generally speaking, the related testing system is preceded with no efficiency and low precision.

Therefore, in view of this, the inventor proposes the present invention to overcome the above problems based on his expert experience and deliberate research.

### SUMMARY OF THE INVENTION

The primary object of the present invention is provided for a testing system for a radio frequency module. The testing system isolates and shields the RF signal so that the interference of the signal are reduced and the manufacture efficiency of the testing is further improved.

Another object of the present invention is to provide a testing system for a radio frequency module. The manufacturing cost of the system is reduced and the system can be automatically controlled.

In order to achieve the above object, the present invention provides a testing system for a radio frequency module. The testing system comprises: a metal casing formed a testing space thereinside, wherein a shielding material layer for shielding radio frequency signal is disposed on an internal surface of the metal casing; a RF testing socket disposed inside the testing space; and a pressing manipulator movably penetrated through the metal casing and extending inside the testing space. The pressing manipulator forces pressure on the radio frequency module disposed on the RF testing socket testing module and the testing process is automatically preceded.

The present invention provides a testing system applied for a RF module and the system can shield and isolate the RF signal so as to improve the manufacture efficiency of the anti-interference RF testing process.

In order to better understand the characteristics and technical contents of the present invention, a detailed description thereof will be made with reference to the accompanying drawings. However, it should be understood that the drawings and the description are illustrative but not used to limit the scope of the present invention.

### BRIEF DESCRIPTION OF THE DRAWINGS

FIG. 1A is a schematic view showing the RF testing system for a radio frequency module according to the present invention;

FIG. 1B is a side view showing the RF testing system for a radio frequency module according to the present invention;

FIG. 2A shows the first embodiment of the insulating layer of the testing system for a radio frequency module according to the present invention; and

FIG. 2B shows the second embodiment of the insulating layer of the testing system for a radio frequency module according to the present invention.

### DETAILED DESCRIPTION OF THE INVENTION

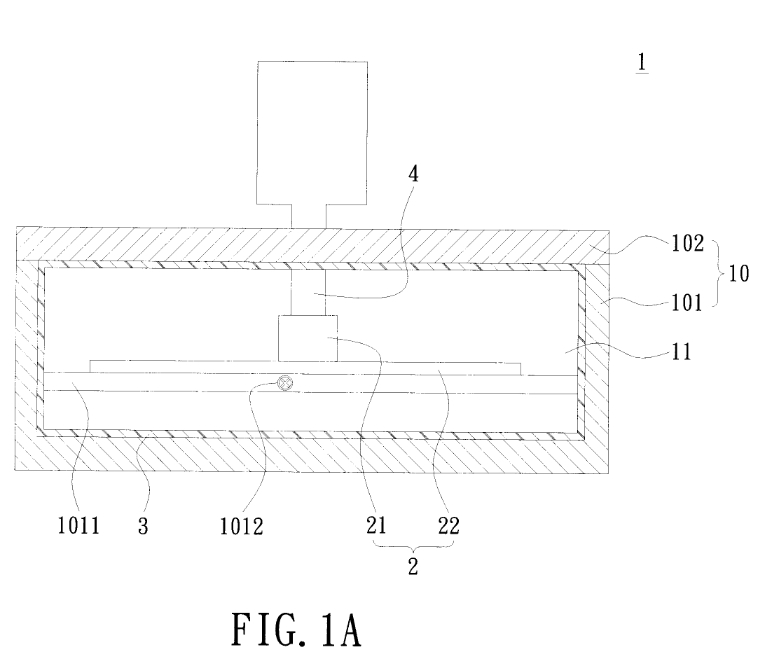

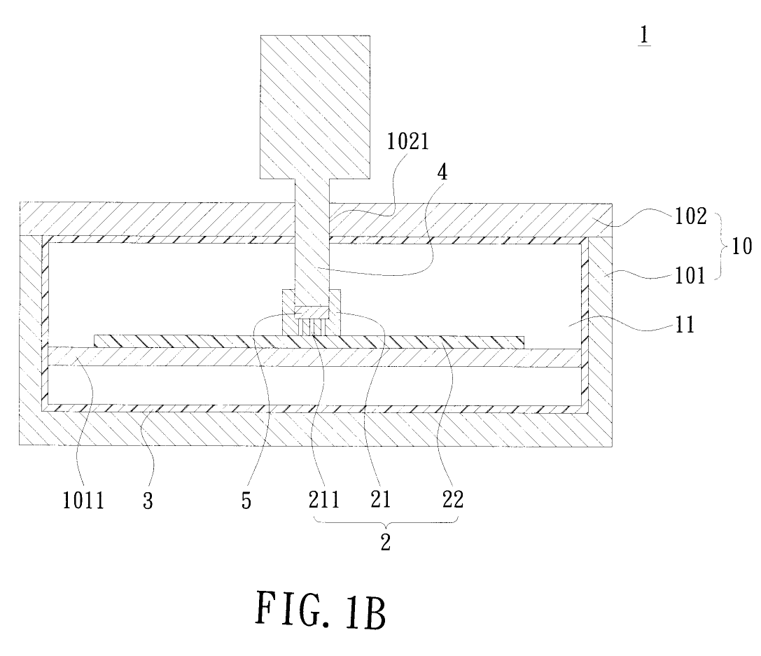

Please refer to FIGS. 1A and 1B, the invention discloses a full automation RF testing system 1 for a radio frequency module. The testing system 1 comprises a metal casing 10, a RF testing socket 2 and a pressing manipulator module 4. The metal casing 10 has a testing space 11 thereinside and a shielding material layer 3 for shielding radio frequency signal is disposed on an internal surface of the metal casing 10. The testing module 2 is disposed in the testing space 11. Furthermore, the pressing manufacture module 4 is movably penetrated through the metal casing and one side of the pressing manipulator 4 extends inside the testing space 11. Depending on the above structure, the pressing manipulator 4 forces pressure on a radio frequency module 5 which is disposed on the RF testing socket 2 for testing the performance of the radio frequency module 5. The testing system 1 is provided for an anti-inference testing environment and an automatic operation so that the efficiency of testing process is improved.

In the embodiment, the metal casing 10 comprises a bottom metal casing 101 and a metal covering 102. The metal covering 102 covers on the bottom metal casing 101 and the bottom metal casing 101 and a metal covering 102 are formed the testing space 11 therebetween. Moreover, a bottom surface of the metal covering 102 and the internal surface of the bottom metal casing 101 are respectively formed the shielding layer 3 so as to prevent the interference of the signal. The shielding material layer 3 is disposed on the surfaces by coating or attaching. In addition, the shielding layer 3 is made from a kind of an absorbing resin for absorbing and shielding radio frequency signal so that the testing space 11 is isolated from the another system.

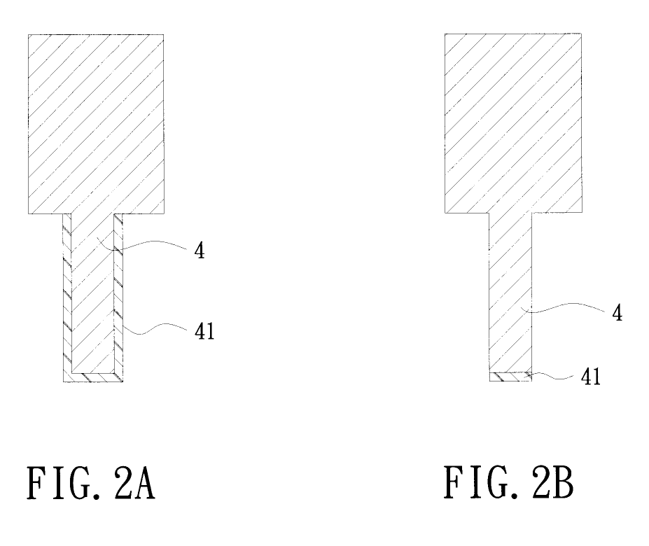

Furthermore, the metal covering 102 has a through hole 1021 thereon and the pressing manipulator 4 extends inside the testing space 11 through the through hole 1021. In detail, the pressing manipulator 4 is a metal arm and the size and outlook of the metal arm is corresponding to the through hole 1021 so that the testing space 11 is isolated for shielding the signal. Furthermore, an insulating layer 41 is disposed on the surface of the pressing manipulator 4, i.e. the metal arm for protecting the radio frequency module 5 from the static electricity. On the other hand, the insulating layer 41 is simply disposed on a surface which contacts with the radio frequency module 5 (please refer to FIG. 2B). In other words, the insulating layer 41 can be formed on entire surface of the metal arm or can only be formed on the surface which contacts with the radio frequency module 5 so that the frequency module 5 is prevented from the static electricity due to the insulating layer 41.

Furthermore, the ratio-frequency testing module 2 (hereinafter RF is used for representing ratio frequency) comprises a RF testing socket 21 and a printed circuit board 22 connected electrically to the RF testing socket. The RF testing socket 21 has a plurality of high frequency testing pins 211. The radio frequency module 5 is setup on the RF testing socket 21 and prepares to be tested. The high frequency testing pins 211 is employed for receiving the signal outputted from the radio frequency module 5 and the signal is analyzed and tested. In detail specification for RF testing module 2, the printed circuit board 22 is prefer a detachable switching board so that the printed circuit board 22 can be efficiently replaced when the printed circuit board 22 is required for repairing or the demand of the testing procedure. Alternatively, the printed circuit board 22 can be a fixed switching board. In other wards, it is convenient for a user to install the printed circuit board 22 depending on the different testing processes. The printed circuit board 22 further connects to a filter, a RF filter and so on. The printed circuit board 22 connects to and outputs the RF signal to a computer for analyzing the signal.

According to this embodiment, the RF testing module 2 is disposed on a supporting member 1011 in the testing space 11. The supporting member 1011 comprises an adjusting device 1012 for adjusting the level of the RF testing module 2. In other word, the radio frequency module 5 has to be level to a horizontal surface so that the pressing manipulator 4 can firmly contact the radio frequency module 5 to execute the testing process with high precision.

In the present invention, the testing system 1 is controlled automatically to execute efficiently the testing processes of the high frequency devices. In detail, the radio frequency module 5 is setup on the RF testing socket 21 of the RF testing module 2 and the RF testing socket 21 has a plurality of high frequency testing pins 211 for receiving the signal outputted from the radio frequency module 5. Next step is covering the metal covering 102 on the bottom metal casing 101 to form the testing space 11 therebetween. The shielding material layer 3 for shielding radio frequency signal is disposed on an internal surface of the metal casing 10 so that the signal outputted from the radio frequency module 5 is absorbed and isolated inside testing space 11. Then, the pressing manipulator 4 is controlled automatically to forces on the radio frequency module 5 and the insulating layer 41 is disposed on the surface of the pressing manipulator 4 for preventing the radio frequency module 5 from the static electricity. At last, the signal outputted from the radio frequency module 5 is transmitted to a computer via the filter, the RF filter and the other devices.

Accordingly, the present invention is provided for an efficient and anti-interference testing system with automatic control.

To sum up, the present invention achieves the following advantages:
1. The shielding material layer 3 is provided for shielding radio frequency signal and a plurality of RF testing systems can proceed simultaneously.
2. The RF testing system is controlled automatically and the efficiency of the testing process is improved. On the other hand, the automatic testing system is executed with high precision. The disadvantages of low testing rate and low-precision of a manual system is solved.
3. The printed circuit board 22 is a detachable switching board so that the printed circuit board 22 can be efficiently replaced when the printed circuit board 22 is required for repairing. In other words, the testing process will not be delay for replacing a broken printed circuit board 22.

Although the present invention has been described with reference to the foregoing preferred embodiment, it will be understood that the invention is not limited to the details thereof. Various equivalent variations and modifications may occur to those skilled in this art in view of the teachings of the present invention. Thus, all such variations and equivalent modifications are also embraced within the scope of the invention as defined in the appended claims.

1. A testing system for a radio frequency module, comprising:
a metal casing enclosure forming a testing space therein, and a shielding material layer disposed on an internal surface of the metal casing for shielding a radio frequency signal;
a radio-frequency testing module disposed in the testing space; and
a pressing manipulator slidingly penetrating into the metal casing enclosure wherein one end of the pressing manipulator is extended in through the testing space and the other end of the pressing manipulator extends out of the metal casing enclosure,
wherein the pressing manipulator forces pressure on the radio frequency module disposed on the radio-frequency testing socket for testing the radio frequency module.

2. The testing system according to claim 1, wherein the metal casing enclosure comprises a metal covering and a bottom metal casing, the bottom metal casing being covered by the metal covering, wherein the shielding material layer is disposed on the internal surfaces of the bottom metal casing and the metal covering.

3. The testing system according to claim 2, wherein the metal covering has a through hole disposed thereon and the pressing manipulator extends in the testing space through the through hole.

4. The testing system according to claim 1, wherein the radio-frequency testing module comprises a radio-frequency testing socket having a plurality of high frequency testing pins and a printed circuit board connected electrically to the testing tooling.

5. The testing system according to claim 4, wherein the radio-frequency testing module is disposed on a supporting piece, wherein the supporting piece has an adjusting device for adjusting a leveling state of the supporting piece.

6. The testing system according to claim 1, wherein the pressing manipulator is a metal arm.

7. The testing system according to claim 6, further comprising an insulating layer being disposed on a surface of the metal arm.

8. The testing system according to claim 7, wherein the insulating layer is disposed on the surface of the metal arm contacted with the radio frequency module for absorbing and shielding radio frequency signal.

9. The testing system according to claim 1, wherein the shielding material layer is made from an absorbing resin for absorbing and shielding a radio frequency signal.
